(19) United States
(12) Patent Application Publication
(10) Pub. No.: US 2025/0114740 A1
(43) Pub. Date: Apr. 10, 2025

(54) COMPACT SCRUBBER FOR PLASMA ABATEMENT GAS STREAM

(71) Applicant: Applied Materials, Inc., Santa Clara, CA (US)

(72) Inventors: Ryan T. DOWNEY, San Jose, CA (US); Shaun W. CRAWFORD, Santa Clara, CA (US)

(21) Appl. No.: 18/377,138

(22) Filed: Oct. 5, 2023

(51) Int. Cl. B01D 53/18; B01D 53/14; B01D 53/32; C23C 16/44

(52) U.S. Cl. CPC B01D 53/18; B01D 53/1456; B01D 53/32; C23C 16/4412; B01D 2252/103; B01D 2257/204; B01D 2258/0216; B01D 2259/818

(57) ABSTRACT

Disclosed herein are an auxiliary abatement device for abating effluent gases, an abatement system including the auxiliary abatement device, and an abatement method for the abatement system. The auxiliary abatement device includes a first chamber comprising a first inlet configured to receive the effluent gases; and a second chamber configured to treat the effluent gases and comprising a second inlet configured to receive a reagent, a first outlet configured to output treated effluent gases, and a second outlet configured to output a byproduct produced by treating the effluent gases. The first chamber and the second chamber are coupled by a conduit. The abatement system includes a plasma unit and an auxiliary abatement device to partially treat the effluent gases. The abatement system utilizes a primary abatement unit disposed downstream of the plasma unit and the auxiliary abatement device to treat the effluent gases in bulk.

### BACKGROUND

### Field

The present disclosure generally relates to an abatement device, an abatement system including the abatement device, and an abatement method for the abatement system. More particularly, embodiments of the present disclosure relate to a compact abatement device for abating effluent gases generated by a semiconductor processing chamber.

### Description of the Related Art

Effluent gases produced during semiconductor manufacturing processes include a variety of harmful compounds which need to be abated before disposal for regulatory compliance and environmental and safety concerns. As the effluent gases include many different types of compounds, the current abatement systems occupy a large footprint to hold complex abatement devices. The current abatement systems also consume an enormous amount of energy during operation.

Accordingly, there is a need to have an improved abatement system.

### SUMMARY

Disclosed herein are a compact scrubber for abating effluent gases, an abatement system including the compact scrubber, and an abatement method for the abatement system. In one example, a compact scrubber includes a first chamber and a second chamber coupled by a conduit. The conduit provides the effluent gases from the first chamber to the second chamber and includes a first end disposed in the first chamber and a second end disposed in the second chamber. The first chamber includes a first inlet configured to receive the effluent gases. The second chamber is configured to treat the effluent gases and includes a second inlet configured to receive a reagent, a first outlet configured to output treated effluent gases, and a second outlet configured to output a byproduct produced by treating the effluent gases. The second end of the conduit in the second chamber is disposed below the second inlet and the first outlet.

In another example, an abatement system includes a plasma abatement unit configured to receive effluent gases from a processing chamber, a pump disposed downstream of and coupled with the plasma abatement unit, a compact scrubber disposed downstream of and coupled with the pump, and a primary abatement unit disposed downstream of and coupled with the compact scrubber. The compact scrubber includes a first chamber and a second chamber coupled by a conduit. The first chamber includes a first inlet configured to receive the effluent gases. The second chamber is configured to treat the effluent gases and includes a second inlet configured to receive a reagent, a first outlet configured to output treated effluent gases, and a second outlet configured to output a byproduct produced by treating the effluent gases.

The abatement method includes outputting effluent gases from a processing chamber to a first abatement unit comprising a plasma unit; outputting the effluent gases from the first abatement unit to a pump; outputting the effluent gases from the pump to a second abatement unit configured to treat the effluent gases with water; and outputting the effluent gases from the second abatement unit to a primary abatement unit configured to treat the effluent gases in bulk.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic diagram of an abatement system, according to an embodiment of the present application.

FIG. 3 illustrates a schematic diagram of an auxiliary device, according to an embodiment.

FIG. 4 illustrates a schematic diagram of a compact scrubber, according to an embodiment.

FIG. 5 illustrates a schematic diagram of a compact scrubber, according to an embodiment.

FIG. 6a illustrates a schematic top view of a spreader according to an embodiment.

FIG. 6b illustrates a schematic top view of a spreader, according to an embodiment.

FIG. 7 illustrates an abatement method of abating effluent gases, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are a compact scrubber for abating effluent gases, an abatement system including the compact scrubber, and an abatement method for the abatement system that are configured to at least partially treat the effluent gases. The compact scrubber is capable of treating certain water soluble gases, such as HF or HCl, in the effluent gases. The compact scrubber has a small physical footprint and can be retrofitted to many existing abatement systems. The compact scrubber is disposed downstream of a plasma abatement unit and upstream of a primary abatement unit. The compact scrubber treats the effluent gases with a moderate efficiency, which reduces the burden on the primary abatement unit downstream of the compact scrubber. For example, effluent gases outputted by a processing chamber can be treated first by a plasma abatement unit. This plasma treatment process may generate certain water soluble gases, such as HF and HCl. The compact scrubber subsequently treats the effluent gases to remove water soluble gases and then outputs the treated effluent gases to the primary abatement unit.

The compact scrubber includes two chambers: one chamber for buffering the effluent gases and the other chamber for treatment, such as absorbing HF or HCl gases with water. The compact scrubber also utilizes a spreader and gas diffusers to increase the exposure of the effluent gases in the water. During operation, fresh water flows into the treatment chamber at a rate that is approximately the same as the rate of contaminated water being released from the treatment chamber. The compact scrubber does not require a large footprint or complex subsystems. This compact scrubber provides an auxiliary abatement device to an abatement system, which can be inexpensive, reliable, and substantially maintenance free.

The present application is not limited to a compact scrubber with a plurality of integrated chambers for partially treating effluent gases. An auxiliary abatement system, which may have a larger footprint than a compact scrubber, is also contemplated by the present application. The auxiliary abatement system may have a plurality of chambers disposed in separated devices. The plurality of chambers of the auxiliary abatement system have similar functions as those chambers of a compact scrubber.

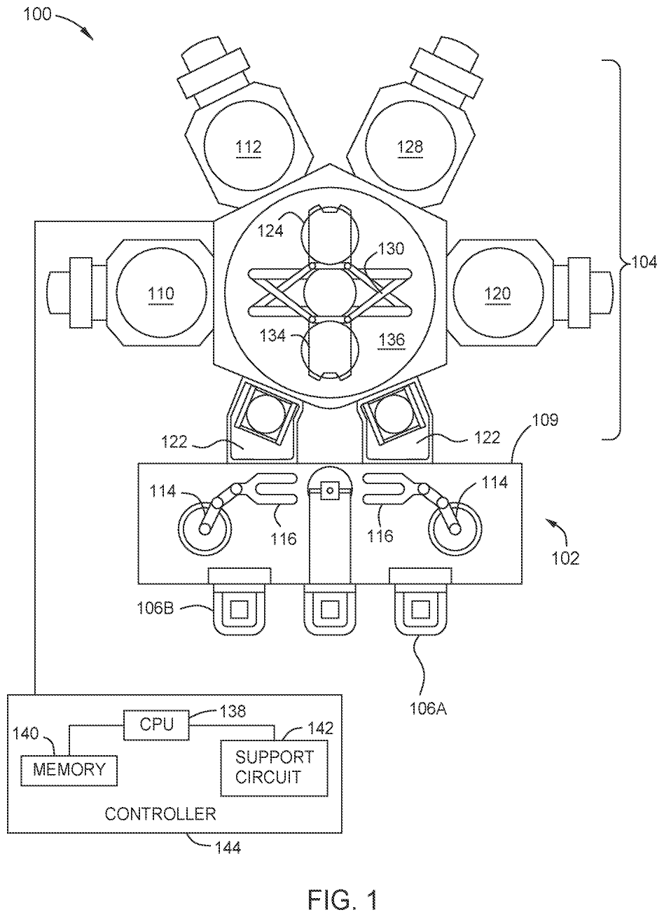

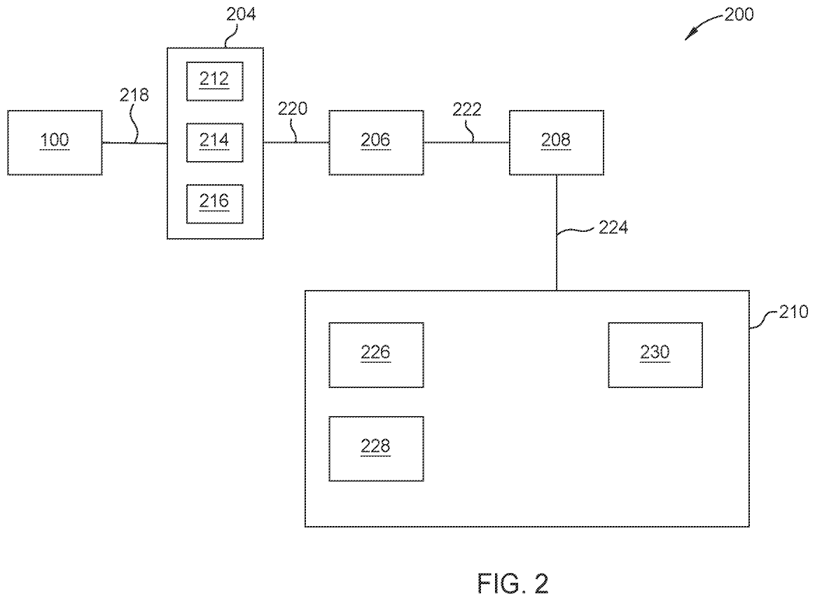

FIG. 1 illustrates a schematic top view of a processing system 100, according to one or more embodiments. The processing system 100 is coupled with an abatement system 200 (FIG. 2) as set forth in the present disclosure. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. According to an embodiment, one or more of the plurality of processing chambers 110, 112, 120, and 128 may be a low temperature EPI chamber, a plasma etch chamber, a chemical vapor deposition chamber, or other processing chamber, which generates effluent gases desirable for abatement. Accordingly, at least one or more of the plurality of processing chambers 110, 112, 120, and 128 has an exhaust connected to an abatement system, as further detailed below with reference to FIG. 2.

Continuing to refer to FIG. 1, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present application). The controller 144 includes a central processing unit (CPU) 138, a memory 140 containing instructions, and support circuits 142 for the CPU. The controller 144 controls various items directly, or via other computers and/or controllers.

FIG. 2 illustrates a schematic diagram of an abatement system 200 coupled to the processing system 100 by a foreline 218, according to an embodiment. The foreline 218 is coupled at one end to the abatement system 200 and at the opposite end to the exhaust port of any one of the processing chambers 110, 112, 120, and 128 of the processing system 100. Processes that may be carried out in the processing chambers include a deposition process, an etching process, annealing or a cleaning process, or other semiconductor processes.

The foreline 218 serves as a conduit that routes effluent gases leaving the processing system 100 to the abatement system 200. Effluent gases may contain material which is undesirable for release into the atmosphere or may damage downstream equipment, such as vacuum pumps. For example, the effluent gases may contain compounds from a dielectric deposition process or from a metal deposition process. Examples of compounds present in the effluent gases include silicon-containing materials, hydrofluorocarbons (HFCs), chlorofluorocarbons (CFCs), or other compounds.

The abatement system 200 includes a pre-pump abatement unit 204, a pump 206, an auxiliary system 208, and a primary abatement unit 210. The foreline 218 couples the processing system 100 with the pre-pump abatement unit 204. A transferring line 220 couples the pre-pump unit 204 with the pump 206. A transferring line 222 couples the pump 206 with the auxiliary system 208. A transferring line 224 couples the auxiliary abatement system 208 with the primary abatement unit 210.

The pre-pump abatement system 204 may include a plasma abatement unit, such as an Aeris-G abatement unit available from Applied Materials, Inc., located in Santa Clara, California, among other suitable systems. The pre-pump abatement system 204 includes a plasma source 214, a reagent delivery unit 212, and a controller 216. The plasma source 214 may be a remote plasma source, an in-line plasma source, or other suitable plasma source for generating a plasma within a treatment region of the pre-pump abatement system 204. The reagent delivery unit 212 delivers one or more reagents, such as abating reagents (which may be, for example, volatilizing or condensing abating reagents) into the foreline 218 or treatment region according to instructions by the controller 216. The abating reagents may include water, ammonia (NH3), H2, CHₓF_{y}, O₂, BCl3, CCl4, SiCl4, NF3, SF4, SF6, SF8, or other compounds. According to an embodiment, nitrogen (N2), argon (Ar), or clean dry air may be introduced into the effluent gases for pressure control. Effluent gases outputted from the treatment region of the pre-pump abatement system 204 may include certain water soluble gases, such as HF, HC, or any other similar gases.

The pump 206 is configured to move the effluent gases from the pre-pump abatement unit 204 to an auxiliary abatement system 208. The auxiliary abatement system 208 may include a compact scrubber. In some embodiments, the pump 206 may be a backing pump, such as a dry mechanical pump or the like. The pump 206 may have a variable pumping capacity with can be set at a desired level.

The auxiliary abatement system 208 is disposed downstream of and coupled to the pump 206. The auxiliary abatement system 208 is operable to treat the effluent gases before the effluent gases enter the primary unit 210. According to an embodiment, the auxiliary abatement system 208 is configured to treat water soluble gases, such as HF, HCL, or other gases. The auxiliary abatement system 208 functions as a compact unit, which does not occupy a substantial amount of physical space. The auxiliary abatement system 208 has moderate efficiency. For example, the auxiliary abatement system 208 may be capable of removing a portion of water soluble gases from the effluent gases, such as 10% to 50% of the water soluble gases. The auxiliary abatement system 208 reduces the burden on the primary abatement unit 210.

The primary abatement unit 210 is disposed downstream and coupled to the auxiliary abatement system 208. The primary abatement unit 210 is configured to treat exhaust gases from the processing chamber 202 in bulk. The primary abatement unit 210 includes a plurality of units for treating the effluent gases, including a water scrubber 226. In addition to a water scrubber 226, other abatement devices, such as a combustion unit 228 and a cooling unit 230, may be optionally included in the primary abatement unit 210.

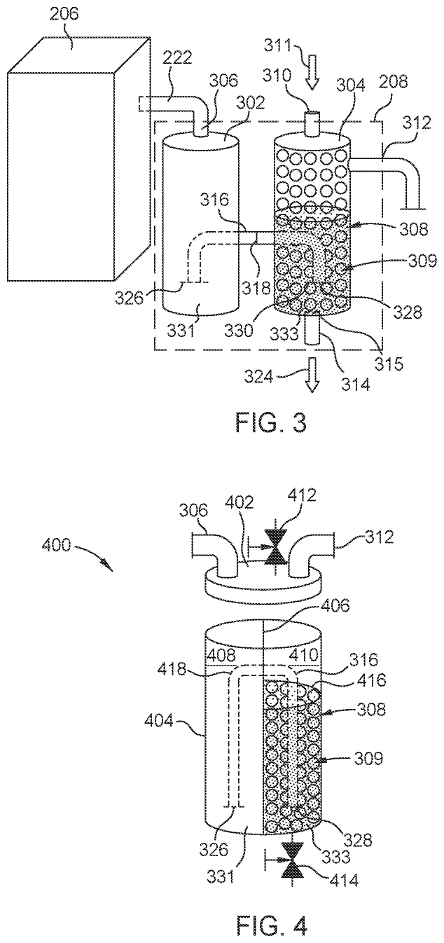

FIG. 3 illustrates a schematic diagram of the auxiliary abatement system 208, according to an embodiment. The auxiliary abatement system 208 includes a first container 302 coupled with a second container 304 via a conduit 316. In one embodiment, the first container 302 and the second container 304 are integrated into one tank, which occupies a smaller footprint and functions as a compact scrubber. In another embodiment, the first container 302 and the second container 304 are disposed in two separated devices having a distance in-between. The effluent gases flow into the first container 302 and then flow into the second container 304 via the conduit 316. The first container 302 includes a first inlet 306 that receives the effluent gases from the pump 206 via the transfer line 222. According to an embodiment, the first container 302 functions as a buffer tank that temporarily stores the effluent gases. According to an embodiment, the first container 302 also holds fluids that flow back from the second container 304 when the pump stops operation. Once the pump restarts operation, the fluid and the effluent gases present in the first container can be pushed back to the second container.

The second container 304 treats the effluence gases with suitable reagents. According to an embodiment, the second container 304 contains a reagent 308 and a plurality of gas diffusers 309. The reagent 308 may include a liquid reagent such as water or any other suitable materials for treating the effluent gases. The reagent 308 may substantially fill the entire second container 304 or a portion of the second container 304. When a portion of the second container 304 is filled with the reagent, an end 328 of the conduit 316 is disposed within the liquid reagent held within the second container 304 and configured to release effluent gases into the liquid reagent.

The gas diffusers 309 are used to enhance the exposure of the effluent gases in the reagent 308. The gas diffusers 309 may be in the shape of balls, discs, plates, tubes or hoses. In an embodiment, the gas diffusers 309 substantially fill the second container 304. The gas diffusers 309 may be perforated or made of porous materials, which are configured to break down the effluent gases to smaller streams or bubbles. The gas diffusers 309 may also increase the travel path (i.e., residence time) of the effluent gases within the reagent 308. In one example, the gas diffusers 309 may be perforated balls, air stones, or any other suitable porous objects.

The second container 304 includes a second inlet 310 configured to receive a fresh reagent 311, a second outlet 314 configured to remove a byproduct 324 from the second container 304, and a first outlet 312 configured to transfer the rest effluent gases out of the second container 304. The second inlet 310 is disposed at an upper region of the second container 304 and adds the fresh reagent 311 to the reagent 308 disposed in the second container 304. The second outlet 314 is disposed at the bottom 315 of the second container 304 and releases byproduct 324 from the second container 304. The byproduct 324 may include water contaminated by water soluble gases, such as HCl or HF, mixed in the reagent 308. According to an embodiment, the flow rates of the fresh reagent 311 into the second container 304 and the releasing rate of the byproduct 324 and reagent 308 exiting the second container 304 are approximately the same such that the second container 304 is not be overfilled or under filled with the reagent 308. As the effluent gases may be lighter than the reagent 308, the first outlet 312 is disposed at an upper region of the second container 304 to receive the effluent gases.

The conduit 316 is operable to allow the effluent gases to flow from the first container 302 to the second container 304. The conduit 316 includes a first end 326 disposed within the first container 302 and a second end 328 disposed within the second container 304. The first and second ends 326 and 328 are disposed within the bottom sections 331 and 333 of the first and second containers 302 and 304, respectively. The bottom sections 331 and 333 may be understood to include sections that are adjacent to bottoms of the first and second containers 302 and 304. The bottom sections 331 and 333 may be about one third, one forth, or one fifth of the heights of the first and second containers 302 and 304. When the amount of reagent in the second container 304 is used as a reference, the bottom sections 331 and 333 may be about one half, one third, one fourth, or one fifth of the height of the reagent contained in the second container 304.

In an embodiment, liquid reagents may be sucked into the first container 302 when the pump 206 stops operation and then pushed back to the second container 304 when the pump 206 restarts operation. To allow the liquid reagent in the first container 302 to flow into the conduit 316, the first end 302 of the conduit 316 is disposed within the liquid reagent that are sucked into the first container 302. According to an embodiment, the first end 326 may be disposed at an even lower position than that of the second end 328.

As shown in FIG. 3, the first end 326 is disposed below the first inlet 306. The second end 328 is disposed below the second inlet 310 and the first outlet 321. The second end 328 is disposed above the second outlet 314. The second end 328 is directed downward and guides the effluent gas toward a bottom of the second container 304 to increase the exposure of the effluent gases in the reagent 308.

According to an embodiment, the conduit 316 has an inverted U shape. The conduit 316 may include a one way valve 318 that substantially prevents back flow from the second container 304 to the first container 302. According to an embodiment, the second end 328 includes a spreader 330 configured to disperse the effluent gases in the reagent 308 present in the bottom region of the second container 304. For example, the spreader 330 can break a single stream of effluent gases into many smaller streams of effluent gases. The spreader 330 may include a showerhead, sparger pipes, or any other suitable devices.

The first container 302, the conduit 316, and the second container 304 is made of a material that is corrosion resistant to the effluent gases. According to an embodiment, suitable corrosion resistant materials include metal (such as stainless steel and aluminum), high performance plastic (such as HDPE, PTFE, FEP, and PEEK), or other suitable material.

FIG. 4 illustrates a schematic diagram of a compact scrubber 400, according to an embodiment. Comparing with the auxiliary abatement system 208 in FIG. 3, the compact scrubber 400 in FIG. 4 may have a smaller footprint. The compact scrubber 400 include a tank 404 and a lid 402. The tank 404 includes two chambers 408 and 410 separated by a divider 406. Similar with FIG. 3, a conduit 316 couples the first chamber 408 and the second chamber 410. The conduit 316 may have an inverted U shape, whose height 418 is above the level 416 of the reagent 308 in the second container 410. The conduit 326 has a first end 326 and a second end 328. The second end 328 may include a spreader 330. The first chamber 408 buffers the effluent gases. The second chamber 410 includes the reagent 308 and the diffuser 309. According to an embodiment, the second chamber 410 includes a release control valve 414 disposed at the bottom. The release control valve 414 is operable to release byproducts from the second container 410 at a predetermined rate. The byproducts may include water contaminated with water soluble gases, such as HF or HCl.

The lid 402 may be coupled to the tank 404 via a hinge or be detachable from the tank 404. In one example, the lid 402 can be detached from the tank 404 for maintenance, cleaning, or for other reasons. For example, the lid 402 may be removed to allow the gas diffusers 309 to be replaced. In another example, the lid 402 may be removed to allow the spreader to be cleaned. According to an embodiment, the first inlet 306, the second inlet 310, and a reagent control valve 412 are disposed on the lid 402. This configuration can ease the service or replacement of the tank 404. The reagent control valve 412 is operable to flow fresh reagent into the second chamber 410 at the same predetermined rate as the release control valve 414.

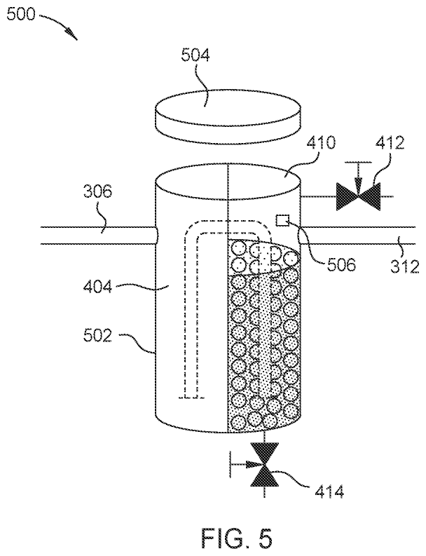

FIG. 5 illustrates a schematic diagram of a compact scrubber 500, according to an embodiment. Comparing with the compact scrubber 400 in FIG. 4, the compact scrubber 500 in FIG. 5 has the first inlet 306, the second outlet 310, and the reagent control valve 412 disposed at a side wall 502 of the tank 404. The lid 504 can be more easily detached from the tank 404 compared with the lid 402 in FIG. 4 because the lid 504 has fewer attached parts. According to an embodiment, sensors 506 may be further included in the second chamber 410 for monitoring the conditions of the compact scrubber 500. The sensors 506 may include a temperature sensor, a pH meter, a conductivity meter, a water level sensor, or other suitable sensors.

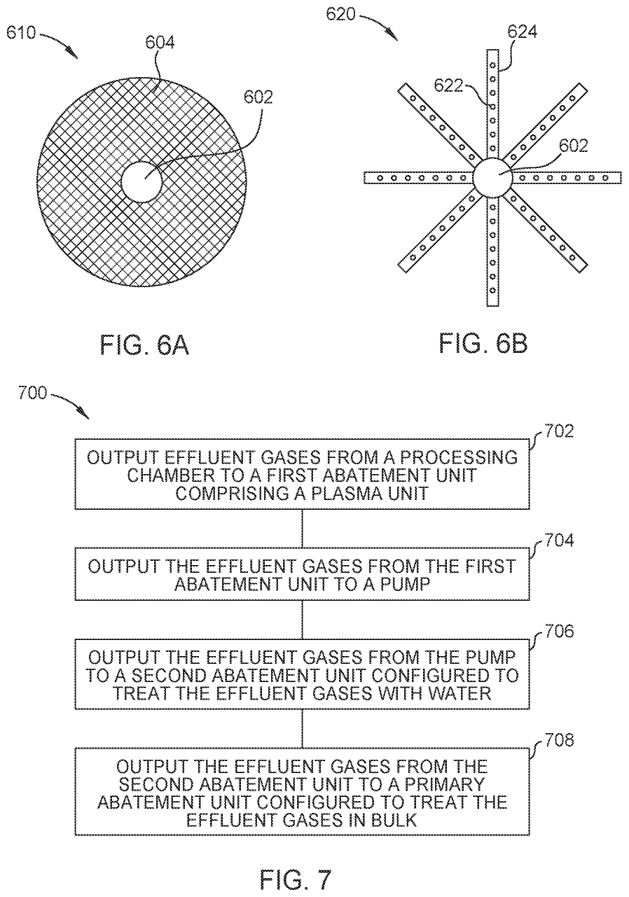

FIG. 6a illustrates a schematic top view of a spreader 610 according to an embodiment. The spreader 610 can be attached to the second end 328 of the conduit 316 shown in FIG. 3 to replace the spreader 330. The spreader 610 may include a showerhead including a central port 602 and a plurality of micro-dispensers 604. The central port 602 receives the effluent gases and distributes them to the micro-dispensers 604. The micro-dispensers 604 include fine outlets that allow the effluent gases flow into the reagent 308.

FIG. 6b illustrates a schematic top view of a spreader 620, according to an embodiment. The spreader 620 can be attached to the second end 328 of the conduit 316 shown in FIG. 3 to replace the spreader 330. The spreader 620 includes a central port 602 and a plurality of sparger pipes 624. For example, the spreader 620 includes 8 sparger pipes extending radially outward from the central port 602. Each sparger pipe 624 includes a plurality of dispensing ports 622. The dispensing port 622 may have a greater diameter than that of the micro-dispensers 604 of FIG. 6a. The large diameter of the dispensing port 622 can avoid clogging due to solid particles generated during the treatment process. According to an embodiment, the diameter of the dispensing ports 622 is greater than diameters of typical solids formed in the effluent gases during an abatement process. The diameter of the dispensing ports 622 may be at least 0.5 mm, 1 mm, or 5 mm.

FIG. 7 illustrates an abatement method 700 of abating effluent gases, according to an embodiment. At operation 702, effluent gases are generated within a processing chamber. The effluent gases are exhausted from the processing chamber to a first abatement unit comprising a plasma unit. At operation 704, the first abatement unit treats the effluent gases with plasma and outputs the treated effluent gases to a pump. At operation 706, the pump outputs the treated effluent gases to a second abatement unit. The second abatement unit includes a compact scrubber as set forth in the present application. The second abatement unit is configured to treat the effluent gases within the compact scrubber with water. The second abatement unit may partially treat effluent gases at moderate efficiency. At operation 708, the compact scrubber outputs scrubber treated effluent gases to a primary abatement unit configured to finally treat the effluent gases in bulk.

According to embodiments of the abatement method, reagents, such as fresh water, may be added to the compact scrubber at a first rate. The fluid with absorbed effluent gases may be released from the compact scrubber at a second rate approximately the same as the first rate. Inside the compact scrubber, the effluent gases is received by a first chamber, and then output from the first chamber to a second chamber. The effluent gases is released into the second chamber via a spreader. The effluent gases flow through the porous materials disposed in the second chamber. During operation, when the pump stops operation, the fluid in the second chamber may flow back into the first chamber; and once the pump restarts operation, the fluid in the first chamber is pushed back into the second chamber.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. An auxiliary abatement system for abating effluent gases comprising:
a first chamber comprising a first inlet configured to receive the effluent gases; and
a second chamber configured to treat the effluent gases and comprising a second inlet configured to receive a liquid reagent, a first outlet configured to output treated effluent gases, and a second outlet configured to output a byproduct produced by treating the effluent gases; and
a conduit coupling the first chamber to the second chamber to provide the effluent gases from the first chamber to the second chamber and comprising a first end disposed in the first chamber and a second end disposed in the second chamber, the second end in the second chamber being disposed below the second inlet and the first outlet.

2. The auxiliary abatement system according to claim 1, comprising:
a tank containing both the first and the second chambers.

3. The auxiliary abatement system of claim 2, comprising:
a lid covering the tank and coupled with the first and second inlets.

4. The auxiliary abatement system of claim 3, wherein the lid is coupled with the first outlet.

5. The auxiliary abatement system of claim 2, wherein the second outlet is disposed at a bottom of the tank, and the second inlet directs the liquid reagent towards the bottom of the tank.

6. The auxiliary abatement system of claim 1, wherein the conduit has an inverted U-shape, and the second end of the conduit is disposed within a bottom section of the second chamber.

7. The auxiliary abatement system of claim 6, wherein the conduit includes a spreader disposed within the second chamber and comprising outlets that face downwardly toward the bottom of the second chamber.

8. The auxiliary abatement system of claim 7, wherein the first end of the conduit is disposed within a bottom section of the first chamber.

9. The auxiliary abatement system of claim 1, comprising porous materials disposed in the second chamber.

10. The auxiliary abatement system of claim 1, wherein the first chamber and the second chamber are contained in two separated devices, respectively.

11. The auxiliary abatement system of claim 2, wherein the second inlet and the first outlet are disposed on a side wall of the second chamber.

12. The auxiliary abatement system of claim 8, wherein the first end is disposed at a lower position than the second end, the bottom section of the second container is filled with the liquid reagent, the second end of the conduit is disposed within the liquid reagent.

13. An abatement system, comprising:
a plasma abatement unit configured to receive effluent gases from a processing chamber;
a pump disposed downstream of and coupled with the plasma abatement unit;
an auxiliary abatement system disposed downstream of and coupled with the pump,
wherein the auxiliary abatement system comprises a first chamber coupled with a second chamber via a conduit that is configured to provide the effluent gases from the first chamber to the second chamber and comprises a first end disposed in the first chamber and a second end disposed in the second chamber, and
wherein the first chamber comprises a first inlet configured to receive the effluent gases; and a second chamber comprises a second inlet configured to receive a liquid reagent, a first outlet configured to output treated effluent gases, and a second outlet configured to output a byproduct produced by treating the effluent gases, the second end of the conduit being disposed below the second inlet and the first outlet; and
a primary abatement unit disposed downstream of and coupled with the auxiliary abatement system.

14. The abatement system of claim 13, wherein the auxiliary abatement system comprises:
a tank containing both the first and the second chambers; and
a lid covering the tank.

15. The abatement system of claim 14, wherein the conduit includes a spreader disposed in the second chamber, the spreader having outlets facing downwardly toward a bottom of the second chamber.

16. The abatement system of claim 15, wherein the conduit is substantially U-shaped, the first end of the conduit is disposed within a bottom section of the first chamber, and the second end of the conduit is disposed within a bottom section of the second chamber.

17. An abatement method comprising:
outputting effluent gases from a processing chamber to a first abatement unit comprising a plasma unit;
outputting the effluent gases from the first abatement unit to a pump;
outputting the effluent gases from the pump to a second abatement unit configured to treat the effluent gases with water;
outputting the effluent gases into a first chamber of the second abatement unit;
outputting, via a conduit, the effluent gases from the first chamber to a second chamber of the second abatement unit;
adding water to the second abatement unit at a first rate;
releasing water with absorbed effluent gases from the second abatement unit at a second rate approximately the same as the first rate; and
outputting the effluent gases from the second chamber of the second abatement unit to a primary abatement unit configured to treat the effluent gases in bulk.

18. The abatement method of claim 17 further comprising:
flowing the effluent gases through porous materials disposed in the second chamber of the second abatement unit.

19. The abatement method of claim 18, further comprising:
releasing, via a spreader of the conduit, the effluent gases into the second chamber.

20. The abatement method of claim 19, further comprising:
receiving, by the first chamber, the water from the second chamber when the pump stops operation; and
flowing the fluid from the first chamber to the second chamber once the pump restarts operation.
